(19) United States
(12) Patent Application Publication
(10) Pub. No.: US 2007/0077366 A1
(43) Pub. Date: Apr. 5, 2007

(54) Plasma doping method and plasma doping apparatus for performing the same

(76) Inventors: Gyeong-Su Keum, Suwon-si (KR); Ji-Hyun Hur, Yongin-si (KR); Jai-Hyung Won, Seoul (KR); No-Hyun Huh, Yongin-si (KR); Jae-Joon Oh, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 11/542,468

(22) Filed: Oct. 4, 2006

(30) Foreign Application Priority Data
Oct. 5, 2005 (KR) 2005-93284

(51) Int. Cl. C23C 14/00; H05H 1/24; G21G 5/00

(52) U.S. Cl. 427/523; 427/569; 250/492.1

(57) ABSTRACT

A method of doping ions into an object using plasma, including providing a doping gas between a first electrode and a second electrode, where an object is disposed between the first and the second electrodes, applying a first power to the first electrode and grounding the second electrode, exciting the doping gas to a plasma state, directing ions toward the object to be doped, applying a second power to the second electrode and grounding the first electrode, and counting a dose of the ions directed toward the second electrode, and an apparatus for performing the same.

### BACKGROUND OF THE INVENTION

1. Field of the Invention

The present invention relates to a method of doping ions into an object, and an apparatus for performing the same. More particularly, the present invention relates to a method of doping ions into an object using plasma in which a doping gas is excited into a plasma state, and positive ions in the plasma are directed into the object, and an apparatus for performing the same.

2. Description of the Related Art

A semiconductor device may be manufactured by sequentially and repeatedly performing various processes, such as a deposition process, a photolithography process, an etching process, an ion implantation process, a polishing process, a cleaning process, a drying process, etc. Recent development of the semiconductor device includes improving a variety of characteristics of the semiconductor device, such as higher storage capacity, faster response speed, greater reliability, etc. Thus, a great deal of research has been carried out in developing ways to improve fine patterning, fine metal wiring, etc., so that semiconductor devices with improved characteristics may be realized.

In an exemplary ion implantation process, an ion beam may be projected onto a predetermined region of a semiconductor substrate so that the ions may be implanted into the predetermined region. The ion implantation process may offer advantages over a thermal diffusion process, since an amount of the ions implanted into the predetermined region, and an ion implantation depth, may easily be controlled.

An exemplary ion beam implantation apparatus may include an ion source generator, a beam line chamber, and an end station chamber. An exemplary operation of such an apparatus may include the ion source generator ionizing a source gas using a thermal electron emission. The beam line chamber may direct ions supplied by the ion source generator toward the end station chamber, in which at least one semiconductor substrate may be disposed.

However, to develop a next generation semiconductor device having a high degree of integration and a high performance capacity, an ion beam implantation apparatus capable of generating a large amount of ions, while operating at a low energy, is required. Also, it may be essential for this new semiconductor device to have a junction portion having a depth of about 100 Å to about 200 Å. Thus, the ion beam implantation apparatus may be required to have a dose of at least about 2×10¹⁶ atoms/cm² and energy below about 5 keV. Unfortunately, a conventional ion beam implantation apparatus may have a dose of below about 1×10¹⁵ atoms/cm² and energy above about 10 keV. In this regard, the conventional ion beam implantation apparatus may not be particularly suitable for producing the next generation semiconductor device. Also, the depth of the junction portion greatly depends on a doping energy level, but since the conventional ion beam implantation apparatus has such a high doping energy level, the semiconductor device may have a very deep junction portion. Thus, the conventional ion beam implantation apparatus may not be desirable for the next generation semiconductor device.

Another doping process is a plasma doping process. In an exemplary plasma doping process, a doping gas may be excited into a plasma state, and ions in the plasma may be directed towards a cathode. The ions may be implanted into a semiconductor substrate disposed on the cathode. The plasma doping process may be employed in a method of forming a dual-poly gate. Additionally, the plasma doping process may be 10 times, or more, efficient than the ion implantation process, so the plasma doping process may also be employed in various other fields and applications.

The doping process requires a dose counting technique. In the conventional ion implantation process, a faraday cup may be in a passage of a beam line to count a dose of implanted ions. However, the same technique may not be suitable for the plasma doping process. Thus, a technique for determining the dose of the implanted ions by collecting ions within a faraday cup disposed adjacent to a semiconductor substrate has been developed.

FIG. 1 illustrates a cross-sectional view of a conventional apparatus configured to dope ions into a semiconductor substrate using plasma.

Referring to FIG. 1, a platen 20 configured to support a semiconductor substrate (not illustrated) may be disposed in a plasma doping chamber 10. An anode 30 may be over the platen 20. A faraday cup 41 may be adjacent to the platen 20, and the faraday cup 41 may be connected to a dose counter 45. The faraday cup 41 may have a ring shape from a plan view (not illustrated). A power source 50 may be connected to the platen 20. A shield 25 may be over the faraday cup 41.

In an exemplary operation, when the anode 30 is grounded and a bias power is applied to the platen 20, a doping gas in the doping chamber 10 may be excited to a plasma state, and ions included in the plasma may be directed toward the platen 20. Some of the ions may be directed toward the semiconductor substrate, and may be doped into the semiconductor substrate. The rest of the ions may be directed toward the faraday cup 41, and collected in the faraday cup 41 to be counted by the dose counter 45.

FIG. 2 illustrates a graph of an amount of ions collected by the faraday cup 41 in FIG. 1. In FIG. 2, the horizontal axis “POINT” represents a distance from a central point of the semiconductor substrate on the platen 20. The vertical axis “Rs” represents a dose of ions on the semiconductor substrate.

Referring to FIG. 2, the dose of ions Rs does not have much variation in central portion ZONE1 to ZONE3 of the semiconductor substrate as the distance POINT increases, but the dose of ions Rs increasingly varies in peripheral portion ZONE4 of the semiconductor substrate, as the distance POINT increases. Actually, the dose of ions Rs may have a value of about 136 to about 139 in the central portion ZONE1 to ZONE3, but the dose of ions Rs may have a value of about 135 to about 141 in the peripheral portion ZONE4. Further, the dose of ions Rs may have an increased number of variations in an area adjacent to the semiconductor substrate in which the faraday cup 41 is disposed. Thus, ions collected by the faraday cup 41 may be quite different from those actually doped into the semiconductor substrate.

Referring now to FIG. 1, when the faraday cup 41 is disposed adjacent to the platen 20, the ions doped into the semiconductor substrate may not be exactly counted based on the ions collected by the faraday cup 41. Further, arcing may occur due to the faraday cup 41 and the shield 25, which may damage the semiconductor substrate.

Even though die sizes and process margins have been decreased as semiconductor devices have become more highly integrated, development of the semiconductor devices has been hampered due to the above-mentioned problems.

### SUMMARY OF THE INVENTION

The present invention is therefore directed to a plasma doping method, and a plasma doping apparatus for performing the same, which substantially overcome one or more of the problems due to the limitations and disadvantages of the related art.

It is therefore a feature of an exemplary embodiment of the present invention to provide a method of doping ions into an object using plasma, the method directed to doping the object with ions at a precise dose.

It is therefore another feature of an exemplary embodiment of the present invention to provide an apparatus that is configured to effectively perform the method of doping the ions into the object using plasma.

At least one of the above features and advantages of the present invention may be realized by providing a method of doping ions into an object using plasma, which may include providing a doping gas between a first electrode and a second electrode, and an object may be disposed between the first and the second electrodes, applying a first power to the first electrode and grounding the second electrode, exciting the doping gas to a plasma state, directing ions included in the plasma toward the object to be doped, applying a second power to the second electrode and grounding the first electrode, and counting a dose of the ions directed toward the second electrode.

The method may include alternately applying the first and the second powers to the first and the second electrodes, respectively, the first and the second powers may have substantially the same waveforms.

Counting the dose of the ions may include counting the ions using a faraday cup, the faraday cup may be positioned in correspondence to a hole in the second electrode, and the faraday cup may be positioned to receive the ions directed toward the second electrode. There may be a plurality of faraday cups and a plurality of holes. Counting the dose of the ions may further include determining a dose of ions doped into a plurality of regions of the object based on the ions collected in each faraday cup.

Determining the dose of the ions doped into the plurality of regions of the object based on the ions collected in each faraday cup may include mapping a relationship between the position of each faraday cup with respect to each region of the object.

At least one of the above and other features and advantages of the present invention may also be realized by providing an apparatus configured to dope ions into an object using plasma, the apparatus may include a chamber, a gas supply unit configured to supply a doping gas into the chamber, a first electrode and a second electrode in the chamber, a dose counting unit, and a power supply configured to operate in a first mode and in a second mode, when in the first mode, the power supply may be configured to apply a first power to the first electrode, and a first different power to the second electrode to excite the doping gas to a plasma state, so that the object may be doped with ions included in the plasma, and when in the second mode, the power supply may be configured to apply a second power to the second electrode, and a second different power to the first electrode, so to direct ions toward the dose counting unit.

The power supply may be configured to alternately apply the first and the second powers to the first and the second electrodes, respectively, the first and the second powers may have substantially the same waveforms.

The power supply unit may include a first switch and alternately connecting the first electrode to the first power and the first different power, and a second switch alternately connecting the second electrode to the second power and the second different power.

The dose counting unit may include a first faraday cup positioned in correspondence to a hole in the second electrode, the first faraday cup may face the object, and a dose counter may be connected to the first faraday cup to count a dose of ions collected by the first faraday cup.

The apparatus may further include a second faraday cup positioned in correspondence to a second hole, the second faraday cup may face the object, and a second dose counter may be connected to the second faraday cup to count a dose of ions collected by the second faraday cup.

The first and the second faraday cups may be disposed along concentric circles on the second electrode. The first and the second faraday cups may have shapes and sizes substantially corresponding to shapes and sizes of the first and the second holes in the second electrode. The first and the second faraday cups and the first and the second holes may have bar shapes.

The apparatus may include a vacuum unit configured to control an internal pressure of the chamber. The first different power may be ground. The second different power may be ground. The first electrode may be configured to support the object and the second electrode may be disposed over the object. The first electrode may be disposed at a lower portion of the chamber and the second electrode may be disposed at an upper portion of the chamber. The first electrode and the second electrode may have substantially the same area.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a conventional apparatus configured to dope ions into a semiconductor substrate using plasma;

FIG. 2 illustrates a graph of an amount of ions collected by a faraday cup illustrated in FIG. 1;

FIG. 3 illustrates a cross-sectional view of an apparatus configured to dope ions into a substrate using plasma in accordance with an exemplary embodiment of the present invention;

FIG. 4 illustrates a graph of a first power and a second power applied to a first electrode and a second electrode in FIG. 3, respectively;

FIG. 5 illustrates a plan view of a faraday cup and the second electrode in FIG. 3 in accordance with an exemplary embodiment of the present invention;

FIG. 6 illustrates a plan view of a faraday cup and a second electrode in accordance with another exemplary embodiment of the present invention;

FIG. 7 illustrates a plan view of a faraday cup and a second electrode in accordance with still another exemplary embodiment of the present invention; and

FIG. 8 illustrates a flow chart of a plasma doping method in accordance with exemplary embodiments of the present invention.

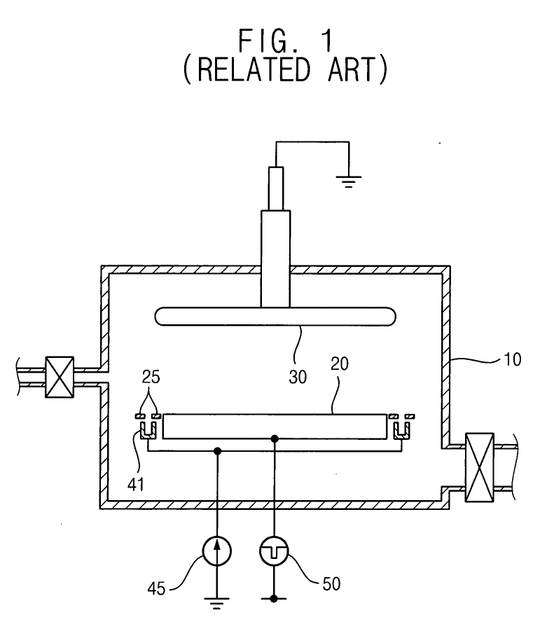

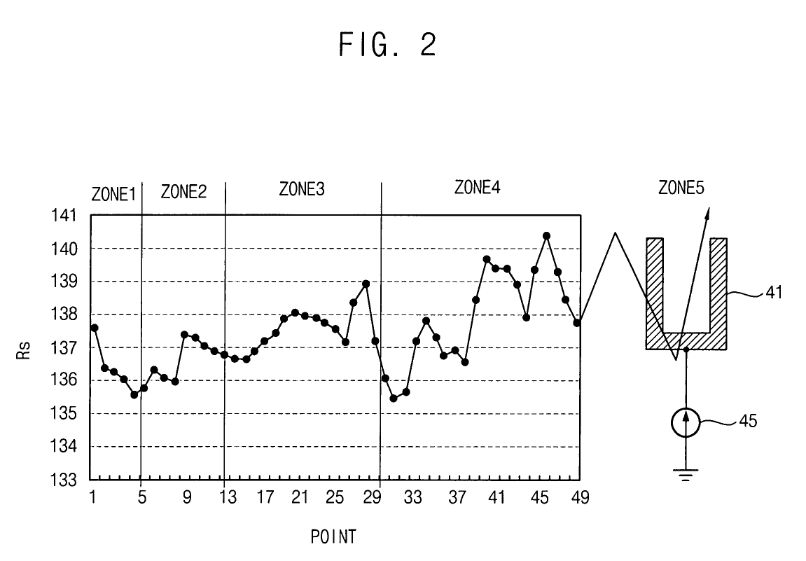

### DETAILED DESCRIPTION OF THE INVENTION

Korean Patent Application No. 2005-93284 filed on Oct. 5, 2005, in the Korean Intellectual Property Office, and entitled: “Plasma Doping Method and Plasma Doping Apparatus for Performing the Same,” is incorporated by reference herein in its entirety.

The present invention will now be described more fully hereinafter with reference to the accompanying figures, in which exemplary embodiments of the invention are illustrated. The present invention may, however, be embodied in different forms and should not be construed as limited to the exemplary embodiments set forth herein. Rather, these embodiments are provided so that this disclosure will be thorough and complete, and will fully convey the scope of the present invention to those skilled in the art. In the accompanying drawings, the dimensions and relative dimensions of elements, layers, and regions may be exaggerated for clarity of illustration.

It will be understood that when an element or layer is referred to as being “on,” “connected to” or “coupled to” another element or layer, it can be directly on, connected or coupled to the other element or layer, or intervening elements or layers may be present. In contrast, when an element or layer is referred to as being “directly on,” “directly connected to” or “directly coupled to” another element or layer, there are no intervening elements or layers present. In addition, it will also be understood that when an element or layer is referred to as being “between” two elements or layers, it can be the only element or layer “between” the two elements or two layers, or one or more intervening elements or layers may also be present.

Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer and/or section from another element, component, region, layer and/or section. Thus, a first element, component, region, layer and/or section discussed below could be termed a second element, component, region, layer and/or section without departing from the teachings of the present invention.

Spatially relative terms, such as “beneath,” “below,” “under,” “lower,” “above,” “upper”, and the like, may be used herein for ease of description to describe one element or feature's relationship to another element(s) or feature(s) as illustrated in the accompanying figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations), and the spatially relative descriptors used herein interpreted accordingly. Further, it will be understood that when an element or layer is referred to as being, for example, “under” another element or layer, it can be directly “under”, or one or more intervening elements or layers may also be present.

The terminology used herein is for the purpose of describing particular exemplary embodiments only, and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein, but are to include deviations in shapes that result, for example, from manufacturing. For example, an implanted region illustrated as a rectangle, will, typically, have rounded or curved features and/or a gradient of implant concentration at its edges, rather than a binary change from implanted to non-implanted region. Likewise, a buried region formed by implantation may result in some implantation in the region between the buried region and the surface through which the implantation takes place. Thus, the regions illustrated in the figures are schematic in nature, and their shapes are not intended to illustrate the actual shape of a region of a device, and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art, and will not be interpreted in an idealized or overly formal sense, unless expressly so defined herein.

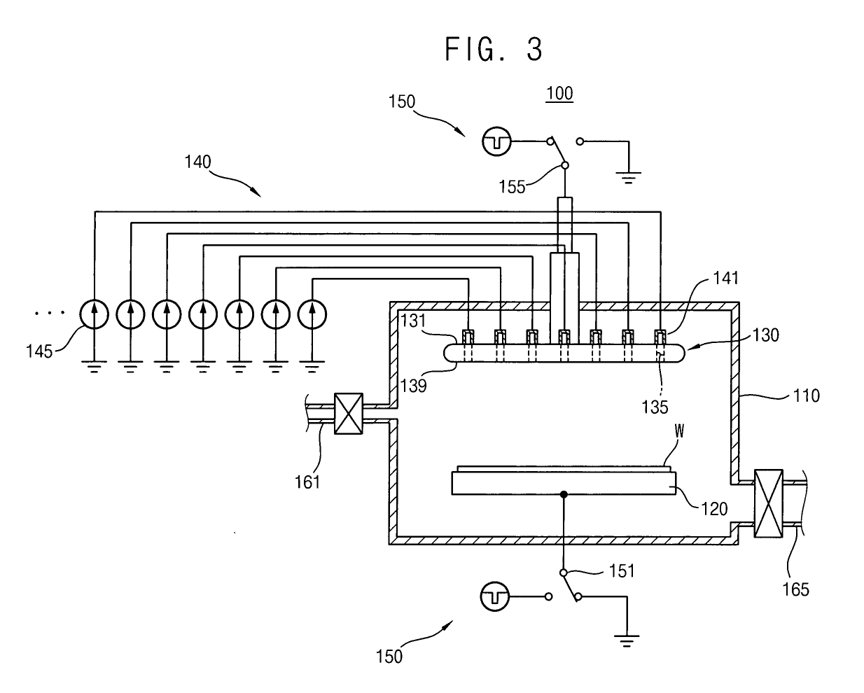

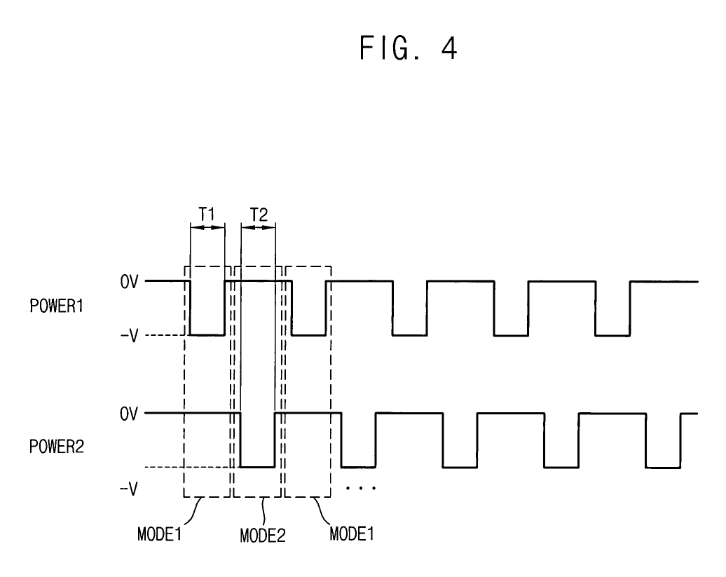

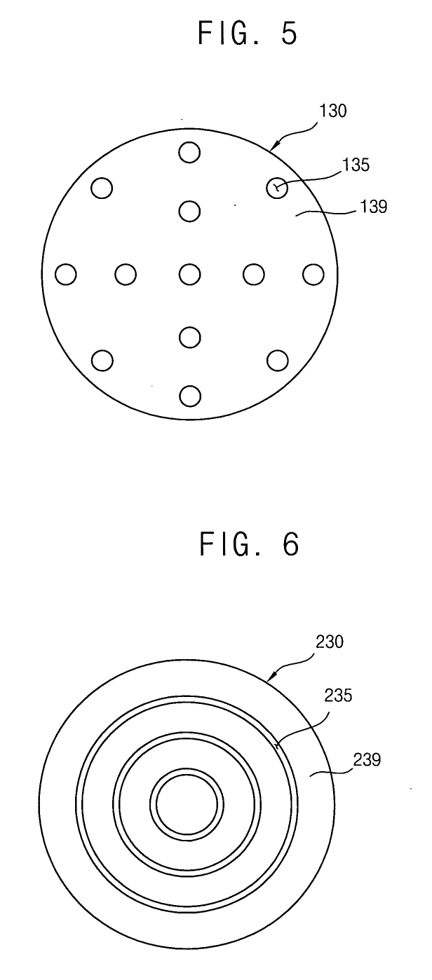

FIG. 3 illustrates a cross-sectional view of a plasma doping apparatus in accordance with an exemplary embodiment of the present invention. FIG. 4 illustrates a graph of a first power and a second power applied to a first electrode and a second electrode in FIG. 3, respectively. FIG. 5 illustrates a plan view of the faraday cup and the second electrode in FIG. 3.

Referring to FIGS. 3 to 5, a plasma doping apparatus 100 may include a chamber 110, a first electrode 120, a second electrode 130, a dose counting unit 140, and a power supply 150. The remaining elements will be discussed in greater detail below. The plasma doping apparatus 100 may be employed for implanting ions into an object, such as a semiconductor substrate W.

The chamber 110 may provide a sealed space configured to perform a plasma doping process. A gas supply unit 161 may be installed on one lateral portion of the chamber 110 to supply a doping gas into the sealed space. A vacuum unit 165 may be installed on another lateral portion of the chamber 110 to evacuate the sealed space. Examples of the doping gas may include a boron trifluoride (BF₃) gas, a nitrogen (N₂) gas, an argon (Ar) gas, a phosphine (PH₃) gas, an arsine (AsH₃) gas, combinations thereof, etc.

The doping gas may be repeatedly supplied into the sealed space of the chamber 110 so that the plasma doping process may be repeatedly performed. A mass flow controller (MFC) (not illustrated) may be additionally installed at the gas supply unit 161 to control a flow rate of the doping gas flowing into the sealed space.

The first electrode 120 may be at a lower portion of the chamber 110, and configured to support the semiconductor substrate W. The second electrode 130 may be at an upper portion of the chamber 110.

The first electrode 120 may include a conductive material, and may have a circular plate shape. The first electrode 120 may additionally include lift pins (not illustrated) configured to support the semiconductor substrate W thereon, and may be connected to a motor (not illustrated) configured to revolve the first electrode 120.

The second electrode 130 may be over the first electrode 120. The second electrode may face the semiconductor substrate W on the first electrode 120. The second electrode 130 may have an area substantially the same as that of the first electrode 120 from a plan view.

The power supply 150 may be connected to the first and the second electrodes 120 and 130. The power supply 150 may be operated in a first mode MODE1 and in a second mode MODE2. In the first mode MODE1, a first power POWER1 may be applied to the first electrode 120. The second electrode 130 may be grounded. In the first mode MODE 1, ions from the plasma may be doped into the semiconductor substrate W.

In the second mode MODE2, a second power POWER2 may be applied to the second electrode 130. The first electrode 120 may be grounded, thereby directing the ions in the plasma toward the dose counting unit 140.

The power supply 150 may further include a first switch 151 and a second switch 155. The power supply 150 may apply the first power POWER1 to the first electrode 120 when the first switch 151 connects the power supply 150 to the first electrode 120, whereas the first electrode 120 may be grounded when the first switch 151 connects a ground point to the first electrode 120. Similarly, the power supply 150 may apply the second POWER2 to the second electrode 130 when the second switch 155 connects the power supply 150 to the second electrode 130, whereas the second electrode 130 may be grounded when the second switch 155 connects a ground point to the second electrode 130. The first and the second switches 151 and 155 may operate conversely. For example, in the first mode MODE1, the first switch 151 may connect the power supply 150 to the first electrode 120, and the second switch 155 may connect the second electrode 130 to the ground point. In the second mode MODE2, the second switch 155 may connect the power supply 150 to the second electrode 130, and the first switch 151 may connect the first electrode 120 to the ground point.

Referring to FIG. 4, the first and the second powers POWER1 and POWER2 may have substantially the same waveforms and may have a predetermined phase difference with respect to each other. The first and the second powers POWER1 and POWER2 may be provided by a direct current (DC) source. Additionally, the first and the second powers POWER1 and POWER2 may have substantially the same peak voltage, duration, and frequency. Thus, a first duration T1 and a second duration T2 may be substantially the same. For example, the first and the second powers POWER1 and POWER2 may have a peak voltage V of about −100 V to about −50 kV, a duration T1 or T2 of about 1 μs to about 50 μs, and a frequency of about 100 Hz to about 2 kHz.

In the first mode MODE1, when the first power POWER1 may be applied to the first electrode 120 and the second electrode 130 may be grounded, an electrostatic field having a high electric potential difference may be formed in the sealed space of the chamber 110. The first electrode 120 may serve as a cathode, and the second electrode 130 may serve as an anode. Doping gas, supplied into the sealed space, may be influenced by the electrostatic field and excited to a plasma state. Ions in the plasma may be directed toward the first electrode 120 to be doped into the semiconductor substrate W.

In the second mode MODE2, when the second power POWER2 may be applied to the second electrode 130 and the first electrode 120 may be grounded, an electrostatic field having a high electric potential difference may also occur in the sealed space of the chamber 110. The second electrode 130 may serve as a cathode, and the first electrode 120 may serve as an anode. Doping gas, supplied into the sealed space, may be influenced by the electrostatic field and excited to a plasma state, and ions in the plasma may be directed toward the second electrode 130 to be counted by the dose counting unit 140. Since doping gas may be continuously supplied into the sealed space, a plasma atmosphere formed in the chamber 110 in the second mode MODE2 may be substantially the same as that in the first mode MODE1.

The first mode MODE1 may serve as a doping mode and the second mode MODE2 may serve as a dose counting mode. The second mode MODE2 may be substantially the same as the first mode MODE1 except for positions of the cathode and the anode. That is, a dose of ions may be counted under substantially the same conditions as those under which the ions are doped into the semiconductor substrate W. The dose of the ions may be counted by the dose counting unit 140.

Referring back to FIG. 3, the dose counting unit 140 may measure the dose of the ions. The dose counting unit 140 may include a faraday cup 141 and a dose counter 145. The faraday cup 141 may be adjacent to the second electrode 130 to collect the ions in the plasma. The dose counter 145 may measure a current or a voltage generated by the collected ions in the faraday cup 141, and may determine a dose of the collected ions from the measurement results.

The faraday cup 141 may be adjacent to a first side 131 of the second electrode 130, which is an opposite side to a second side 139 facing the semiconductor substrate W. A plurality of faraday cups 141 may be along concentric circles on the first side 131 of the second electrode 130. The faraday cups 141 may be within the semiconductor substrate W area from a plan view.

Referring to FIGS. 3 and 5, a hole 135 may be formed through the second electrode 130 corresponding to position of the faraday cup 141, thereby exposing the faraday cup 141 in a direction toward the semiconductor substrate W. A plurality of the holes 135 may be formed through the second electrode 130, and the holes 135 may be positioned in correspondence to a plurality of the faraday cups 141, respectively.

A plurality of dose counters 145 may also be provided. Each of the dose counters 145 may be connected to each of the faraday cups 141, respectively.

The dose counters 145 may measure a current or a voltage generated by the ions collected in the faraday cups 141. The dose counters 145 may then determine a dose of the ions from the measurement results. However, since the faraday cups 141 may be disposed at different locations, the ions collected by each faraday cup 141 may be different from one another, so that each dose counter 145 may determine different dose results from one another. Accordingly, ions doped into each region of the semiconductor substrate W may be predicted by a mapping method using a relationship between the position of each faraday cup 141 and that of each region of the semiconductor substrate W.

The first and the second modes MODE1 and MODE2 (i.e., the doping mode and the dose counting mode) may have substantially the same plasma atmosphere. Thus, an amount of the ions collected by the faraday cup 141 may be substantially the same as that doped into a region of the semiconductor substrate W, wherein the region is disposed under the faraday cup 141. That is, an amount of the ions doped into the region of the semiconductor substrate W may be predicted from a dose counted by the corresponding dose counter 145.

The faraday cups 141 may be disposed at various positions and in various numbers. Additionally, the plurality of the holes 135 may be formed through the second electrode 130 and may correspond to the positions and the numbers of the faraday cups 141.

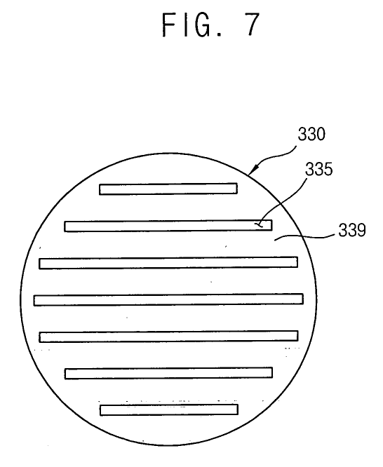

Hereinafter, a faraday cup and a second electrode in accordance with exemplary embodiments of the present invention will be illustrated with reference to FIGS. 6 and 7.

FIG. 6 illustrates a plan view of a faraday cup and a second electrode in accordance with another exemplary embodiment of the present invention.

Referring to FIG. 6, a plurality of holes 235 having concentric ring shapes may be formed through a second electrode 230. A second side 239 may face a semiconductor substrate W (see FIG. 3). A plurality of faraday cups 141 (see FIG. 3) may be disposed adjacent to the holes 235 along a first side opposite to the second side 239. For example, each of the faraday cups 141 may have a cylindrical shape having a diameter that substantially corresponds to a width of a corresponding hole 235.

Alternatively, the faraday cups 141 may have concentric ring shapes (not illustrated) from a plan view, and may correspond to the holes 235. That is, each of the faraday cups 141 may have a ring-shaped cross section taken along a horizontal direction, and the ring-shaped cross section may have a width that substantially corresponds to the width of the holes 235. Each of the faraday cups 141 may be adjacent to a corresponding hole 235, and a dose counter 145 (see FIG. 3) may be connected to each of the faraday cups.

FIG. 7 illustrates a plan view of a faraday cup and a second electrode in accordance with still another exemplary embodiment of the present invention.

Referring to FIG. 7, a plurality of holes 335 having bar shapes may be formed though a second electrode 330. A second side 339 may face a semiconductor substrate W (see FIG. 3). Each of the holes 335 may be formed parallel to one another. A plurality of faraday cups 141 (see FIG. 3) may be disposed adjacent to the holes 335 along a first side opposite to the second side 339. For example, each of the faraday cups 141 may have a cylindrical shape having a diameter that substantially corresponds to a width of a corresponding hole 335.

Alternatively, the faraday cups 141 may have bar shapes (not illustrated) from a plan view and may correspond to the holes 335. That is, each of the faraday cups 141 may have a bar-shaped cross section taken along a horizontal direction, and the bar-shaped cross section may have a width that substantially corresponds to the width of the holes 335. Each of the faraday cups 141 may be adjacent to a corresponding hole 335 and a dose counter 145 (see FIG. 3) may be connected to each of the faraday cups.

The faraday cups 141 may be formed in correspondence to holes 135, 235, and 335, respectively, to face the semiconductor substrate W, and may be electrically insulated from the second electrodes 130, 230, and 330, respectively. Additionally, a plurality of faraday cups 141 may be provided and the faraday cups 141 may have various shapes and may vary in aspects of shape and number.

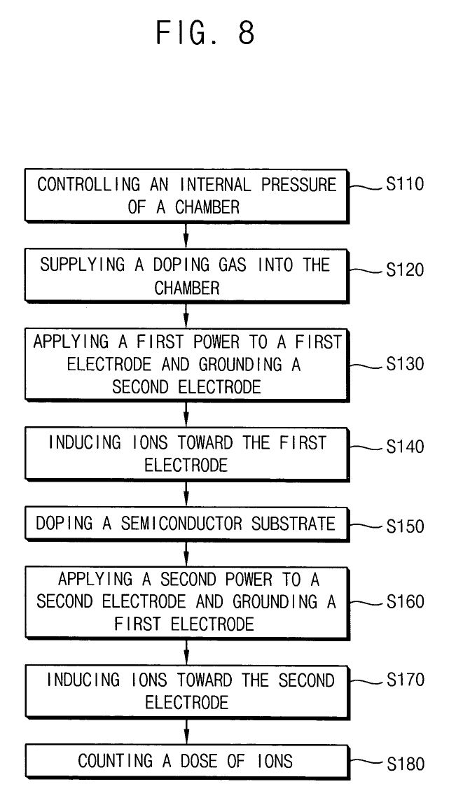

A method of doping ions into an object using plasma in accordance with exemplary embodiments of the present invention will now be described with reference to FIG. 8.

Referring to FIGS. 3 and 8, in step S110, the vacuum unit 165 may evacuate the chamber 110. An inside of the chamber 110 may be evacuated to a pressure of, for example, about 1 mTorr to about 500 mTorr.

In step S120, when the inside of the chamber 110 is evacuated to a predetermined pressure, the gas supply unit 161 may supply a doping gas into the chamber 110. The doping gas may be supplied to the chamber 110 at, for example, a constant flow rate and under a constant pressure. Examples of the doping gas may include a boron trifluoride (BF₃) gas, a nitrogen (N₂) gas, an argon (Ar) gas, a phosphine (PH₃) gas, an arsine (AsH₃) gas, combinations thereof, etc. The doping gas may be uniformly diffused between the first and the second electrodes 120 and 130.

In step S130, a first power POWER1 may be applied to the first electrode 120 and the second electrode 130 may be grounded. The first power POWER1 may have a peak voltage V of about −100 V to about −50 kV, a duration T1 of about 1 μs to about 50 μs, and a frequency of about 100 Hz to about 2 kHz. As the first power POWER1 is applied to the first electrode 120, an electric field having a high potential difference may be generated between the first and the second electrodes 120 and 130.

In step S140, ions in the plasma may be directed toward the first electrode 120.

In step S150, the ions may be doped into the semiconductor substrate W. Generating the plasma and doping the semiconductor substrate W with the ions may be performed simultaneously.

After the doping process of step S150 is performed for a predetermined time period, in step S160, the second power POWER2 may be applied to the second electrode 130 and the first electrode 120 may be grounded. The second power POWER2 may have a peak voltage, duration and frequency which may be substantially the same as those of the first power POWER1. The second electrode 130 may serve as a cathode, and the first electrode 120 may serve as an anode.

When the second power POWER2 is applied to the second electrode 130, an electric field having a high potential difference may be formed between the first and the second electrodes 120 and 130. Since the doping gas may be continuously supplied into the chamber 110, a plasma atmosphere formed in the chamber 110 may be substantially the same as that in the doping step S150.

In step S170, ions included in the plasma may be directed toward the second electrode 130, which serves as the cathode.

In step S180, a dose of the ions may be counted by the dose counting unit 140. The plasma atmosphere formed in the chamber 110 may be substantially the same as that in the doping step S150. Ions that are collected by the faraday cups 141 at various positions may be measured, and the above-mentioned mapping method may be used to determine the amount of ions doped into each region of the semiconductor substrate W. Here, positions of the faraday cups 141 may be variously changed.

When polarities of the first and the second electrodes 120 and 130 are changed, ions accumulated on the semiconductor substrate W during the doping step S150 may be removed from the semiconductor substrate W. The doping step S150 may not be continued for a long time because of the accumulated ions on the semiconductor substrate W. While the doping process is paused to remove the accumulated ions from the semiconductor substrate W, a dose counting step S180 may be performed. When the polarities of the first and second electrodes 120 and 130 are changed in the doping counting step S180, the accumulated ions on the semiconductor substrate W may move to the second electrode 130 that serves as a cathode, and thus the accumulated ions may be easily removed from the semiconductor substrate W.

One or more of the above-described steps, for example, steps S130 to S180, may be repeatedly performed. An amount of the ions doped into the semiconductor substrate W may be precisely measured so that process efficiency and production yield may be improved.

According to the present invention, an amount of ions doped into an object, such as a semiconductor substrate, may be precisely counted by forming a plasma atmosphere substantially the same as that of a doping process, and measuring a dose of the ions at a position substantially the same as that into which ions are doped. Thus, the semiconductor substrate may be precisely processed, and a semiconductor device having superior quality may be accurately manufactured within a short period of time. Additionally, potential damages that may occur by malfunctions during the process may be decreased since the amount of ions may be confirmed in real time.

According to the present invention, a dose of ions doped into an object, such as a semiconductor substrate, may be counted under substantially the same conditions as that under which the semiconductor substrate is being doped with ions. Thus, the semiconductor substrate may be doped with ions of a precise dose, and arcing may be prevented.

Exemplary embodiments of the present invention have been disclosed herein, and although specific terms are employed, they are used and are to be interpreted in a generic and descriptive sense only, and not for purpose of limitation. Accordingly, it will be understood by those of ordinary skill in the art that various changes in form and details may be made without departing from the spirit and scope of the present invention as set forth in the following claims.

What is claimed is:

1. A method of doping ions into an object using plasma, comprising:
providing a doping gas between a first electrode and a second electrode, wherein an object is disposed between the first and the second electrodes;
applying a first power to the first electrode and grounding the second electrode;
exciting the doping gas to a plasma state;
directing ions included in the plasma toward the object to be doped;
applying a second power to the second electrode and grounding the first electrode; and
counting a dose of the ions directed toward the second electrode.

2. The method as claimed in claim 1, including
alternately applying the first and the second powers to the first and the second electrodes, respectively, wherein the first and the second powers have substantially the same waveforms.

3. The method as claimed in claim 1, wherein counting the dose of the ions includes counting the ions using a faraday cup, the faraday cup positioned in correspondence to a hole in the second electrode to receive the ions directed toward the second electrode.

4. The method as claimed in claim 3, wherein there are a plurality of faraday cups and a plurality of holes.

5. The method as claimed in claim 4, wherein counting the dose of the ions further includes determining a dose of ions doped into a plurality of regions of the object based on the ions collected in each faraday cup.

6. The method as claimed in claim 5, wherein determining the dose of the ions doped into the plurality of regions of the object based on the ions collected in each faraday cup includes mapping a relationship between the position of each faraday cup with respect to each region of the object.

7. An apparatus configured to dope ions into an object using plasma, comprising:
a chamber;
a gas supply unit configured to supply a doping gas into the chamber;
a first electrode and a second electrode in the chamber;
a dose counting unit; and
a power supply configured to operate in a first mode and in a second mode,
wherein:
in the first mode, the power supply is configured to apply a first power to the first electrode, and a first different power to the second electrode to excite the doping gas to a plasma state, so that the object is doped with ions included in the plasma, and
in the second mode, the power supply is configured to apply a second power to the second electrode, and a second different power to the first electrode, so as to direct the toward the dose counting unit.

8. The apparatus as claimed in claim 7, wherein the power supply is configured to alternately apply the first and the second powers to the first and the second electrodes, respectively, the first and the second powers have substantially the same waveforms.

9. The apparatus as claimed in claim 7, wherein the power supply unit includes:
a first switch alternately connecting the first electrode to the first power and the first different power; and
a second switch alternately connecting the second electrode to the second power and the second different power.

10. The apparatus as claimed in claim 7, wherein the dose counting unit includes:
a first faraday cup positioned in correspondence to a first hole in the second electrode, the first faraday cup facing the object; and
a dose counter connected to the first faraday cup to count a dose of ions collected by the first faraday cup.

11. The apparatus as claimed in claim 10, further including:
a second faraday cup positioned in correspondence to a second hole in the second electrode, the second faraday cup facing the object; and
a second dose counter connected to the second faraday cup to count a dose of ions collected by the second faraday cup.

12. The apparatus as claimed in claim 11, wherein the first and the second faraday cups are disposed along concentric circles on the second electrode.

13. The apparatus as claimed in claim 11, wherein the first and the second faraday cups have shapes and sizes substantially corresponding to shapes and sizes of the first and the second holes in the second electrode.

14. The apparatus as claimed in claim 13, wherein the first and the second faraday cups and the first and the second holes in the second electrode have bar shapes.

15. The apparatus as claimed in claim 7, further including a vacuum unit configured to control an internal pressure of the chamber.

16. The apparatus as claimed in claim 7, wherein the first different power is ground.

17. The apparatus as claimed in claim 7, wherein the second different power is ground.

18. The apparatus as claimed in claim 7, wherein the first electrode is configured to support the object and the second electrode is disposed over the object.

19. The apparatus as claimed in claim 18, wherein the first electrode is disposed at a lower portion of the chamber and the second electrode is disposed at an upper portion of the chamber.

20. The apparatus as claimed in claim 18, wherein the first electrode and the second electrode have substantially the same area.
